(19) United States
(12) Patent Application Publication
(10) Pub. No.: US 2025/0174575 A1
(43) Pub. Date: May 29, 2025

(54) ELECTRONIC STRUCTURE AND MANUFACTURING METHOD THEREOF, AND ELECTRONIC PACKAGE AND MANUFACTURING METHOD THEREOF

(71) Applicant: SILICONWARE PRECISION INDUSTRIES CO., LTD., Taichung City (TW)

(72) Inventors: Hung-Hsiang FANG, Taichung City (TW); Yu-Chao LEE, Taichung City (TW); Pei-Chien LIN, Taichung City (TW); Hao-Cheng WANG, Taichung City (TW); Hsuan-Jen WANG, Taichung City (TW)

(21) Appl. No.: 18/747,281

(22) Filed: Jun. 18, 2024

(30) Foreign Application Priority Data
Nov. 23, 2023 (TW) 112145403

(51) Int. Cl. H01L 23/00; H01L 21/48; H01L 21/56; H01L 23/498; H01L 23/528

(52) U.S. Cl. CPC H01L 23/562; H01L 21/4853; H01L 21/56; H01L 23/5283; H01L 24/16; H01L 23/49811; H01L 24/32; H01L 24/73; H01L 2224/16227; H01L 2224/32225; H01L 2224/73204; H01L 2924/1815

(57) ABSTRACT

An electronic structure is provided and includes: an electronic body having a first surface and a second surface opposing the first surface; a plurality of conductive bumps disposed on the first surface of the electronic body; a protective layer formed on the first surface of the electronic body and covering the plurality of conductive bumps; and a plurality of grooves formed in the protective layer. A manufacturing method of the electronic structure, and an electronic package and a manufacturing method thereof are further provided.

### CROSS-REFERENCE TO RELATED APPLICATIONS

The present application is based upon and claims the right of priority to TW patent application Ser. No. 11/214,5403, filed Nov. 23, 2023, the disclosure of which is hereby incorporated by reference herein in its entirety for all purposes.

### BACKGROUND

### 1. Technical Field

The present disclosure relates to a semiconductor device, and more particularly, to an electronic structure and an electronic package and a manufacturing method thereof.

### 2. Description of Related Art

In order to ensure the continued miniaturization and multi-function of electronic products and communication equipment, semiconductor packaging needs to develop towards miniaturization in order to facilitate the connection of multiple pins. To this end, many advanced process packaging technologies have been developed in the industry. For example, in advanced process packaging, such as 2.5D packaging process, Fan-Out wiring with Embedded Bridge component process (FO-EB), are commonly used packaging types.

FIG. 1 is a schematic cross-sectional view illustrating a manufacturing method of a conventional semiconductor package 1. As shown in FIG. 1, an electronic structure 1a and a plurality of conductive pillars 13 are disposed on a wiring structure 14 of a carrier board 1b, wherein the electronic structure 1a includes an electronic body 11, a plurality of conductive bumps 111, a circuit portion 12, a plurality of external bumps 122 and a protective layer 19. A plurality of conductive vias 110 are formed in the electronic body 11 and in communication with a first surface 11a and a second surface 11b of the electronic body 11. The plurality of conductive bumps 111 are formed on the first surface 11a of the electronic body 11 and electrically connected to the plurality of conductive vias 110. The circuit portion 12 is disposed on the second surface 11b of the electronic body 11 and includes at least one insulating layer 120 and conductive traces 121 bonded to the insulating layer 120. The plurality of external bumps 122 are formed on the circuit portion 12 and are electrically connected to the plurality of conductive vias 110 via the conductive traces 121. The protective layer 19 is formed on the first surface 11a of the electronic body 11 and covers the plurality of conductive bumps 111.

The electronic structure 1a is disposed on the wiring structure 14 via the plurality of external bumps 122. However, when the electronic structure 1a is disposed on the wiring structure 14 in the die bonding process, the electronic structure 1a is prone to warpage due to the very thin thickness of the electronic body 11 and the large coefficient of thermal expansion (CTE) difference between the protective layer 19 and the electronic body 11 (the protective layer 19 is formed on the first surface 11a of the electronic body 11). The warpage can easily cause the plurality of external bumps 122 to detach from the wiring structure 14, resulting in a non-wetting phenomenon, which leads to quality and reliability problems in subsequent products and a decrease in product yield.

Therefore, how to overcome the above-mentioned problems of the prior art has become an urgent issue to be solved.

### SUMMARY

In view of the various shortcomings of the prior art, the present disclosure provides an electronic structure, which comprises: an electronic body having a first surface and a second surface opposing the first surface; a plurality of conductive bumps disposed on the first surface of the electronic body; a protective layer formed on the first surface of the electronic body and covering the plurality of conductive bumps, wherein an area outside the plurality of conductive bumps and in the protective layer is defined as an open area; and a plurality of grooves formed in the protective layer and located in the open area.

In the aforementioned electronic structure, the plurality of grooves do not penetrate through the protective layer.

In the aforementioned electronic structure, some of the plurality of grooves are exposed from side surfaces of the protective layer.

In the aforementioned electronic structure, an extending direction of the plurality of grooves is a single direction.

In the aforementioned electronic structure, extending directions of the plurality of grooves are transverse and longitudinal and are mutually perpendicular, whereby the plurality of grooves present a grid form.

In the aforementioned electronic structure, an extending direction of each of the plurality of grooves is arranged irregularly.

The present disclosure provides an electronic package, which comprises: a circuit structure having a first side and a second side opposing the first side; the aforementioned electronic structure disposed on the first side of the circuit structure via the first surface of the electronic body; and a plurality of electronic components disposed on the second side of the circuit structure and electrically connected to the circuit structure, wherein the electronic structure is electrically connected to the circuit structure via the plurality of conductive bumps to electrically connect at least two of the plurality of electronic components.

In the aforementioned electronic package, the present disclosure further comprises a cladding layer encapsulating the electronic structure.

In the aforementioned electronic package, the present disclosure further comprises an encapsulation layer encapsulating the plurality of electronic components.

In the aforementioned electronic package, the present disclosure further comprises a carrier structure carrying the electronic structure, wherein the second surface of the electronic body of the electronic structure is disposed on the carrier structure via a plurality of external bumps, and the electronic structure is electrically connected to the carrier structure.

In the aforementioned electronic package, the present disclosure further comprises a plurality of conductive pillars disposed on and electrically connected to the carrier structure and surrounding the electronic structure.

The present disclosure also provides a method of manufacturing an electronic structure, the method comprises: providing an electronic body having a first surface and a second surface opposing the first surface; forming a plurality of conductive bumps on the first surface of the electronic body; forming a protective layer on the first surface of the electronic body to cover the plurality of conductive bumps, wherein an area outside the plurality of conductive bumps and in the protective layer is defined as an open area; and forming a plurality of grooves in the protective layer, wherein the plurality of grooves are located in the open area.

In the aforementioned method, the plurality of grooves do not penetrate through the protective layer.

In the aforementioned method, some of the plurality of grooves are exposed from side surfaces of the protective layer.

In the aforementioned method, an extending direction of the plurality of grooves is a single direction.

In the aforementioned method, extending directions of the plurality of grooves are transverse and longitudinal and are mutually perpendicular, whereby the plurality of grooves present a grid form.

In the aforementioned method, an extending direction of each of the plurality of grooves is arranged irregularly.

The present disclosure also provides a method of manufacturing an electronic package, the method comprises: providing a circuit structure and the aforementioned electronic structure, wherein the circuit structure has a first side and a second side opposing the first side; disposing the first surface of the electronic body of the electronic structure on the first side of the circuit structure; and disposing a plurality of electronic components on the second side of the circuit structure, wherein the plurality of electronic components are electrically connected to the circuit structure, wherein the electronic structure is electrically connected to the circuit structure via the plurality of conductive bumps to electrically connect at least two of the plurality of electronic components.

In the aforementioned method, the present disclosure further comprises forming a cladding layer to encapsulate the electronic structure.

In the aforementioned method, the present disclosure further comprises forming an encapsulation layer to encapsulate the plurality of electronic components.

In the aforementioned method, the present disclosure further comprises disposing the second surface of the electronic body of the electronic structure on a carrier structure via a plurality of external bumps, wherein the electronic structure is electrically connected to the carrier structure.

In the aforementioned method, the present disclosure further comprises forming a plurality of conductive pillars on the carrier structure, wherein the plurality of conductive pillars surround the electronic structure and are electrically connected to the carrier structure.

To sum up, in the electronic structure and electronic package and the manufacturing method thereof of the present disclosure, the plurality of grooves are formed in the protective layer of the electronic structure to effectively release stress and prevent the electronic structure from warping, so that the occurrence of the non-wetting problem of the solder for the external bumps can be avoided in the subsequent processes. In addition, the electronic structure and electronic package and the manufacturing method thereof of the present disclosure can be accomplished by the existing processes and equipment, so there won't be a lot of extra costs.

### BRIEF DESCRIPTION OF THE DRAWINGS

FIG. 1 is a schematic cross-sectional view of a conventional semiconductor package.

FIG. 2A and FIG. 2B-1 are schematic cross-sectional views illustrating a manufacturing method of an electronic structure of the present disclosure.

FIG. 2B-2 is a schematic cross-sectional view illustrating another embodiment of the electronic structure of the present disclosure.

FIG. 2C-1, FIG. 2C-1′, FIG. 2C-2, FIG. 2C-3 and FIG. 2C-4 are schematic top plan views illustrating different embodiments of the electronic structure of the present disclosure.

FIG. 3A, FIG. 3B and FIG. 3C are schematic cross-sectional views illustrating a manufacturing method of an electronic package of the present disclosure.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate the perusal and comprehension of the content of this specification by one skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” “one,” and the like recited herein are for illustrative purposes, and are not meant to limit the scope in which the present disclosure can be implemented. Any variations or modifications to their relative relationships without substantially altering the technical content should also be regarded as within the scope in which the present disclosure can be implemented.

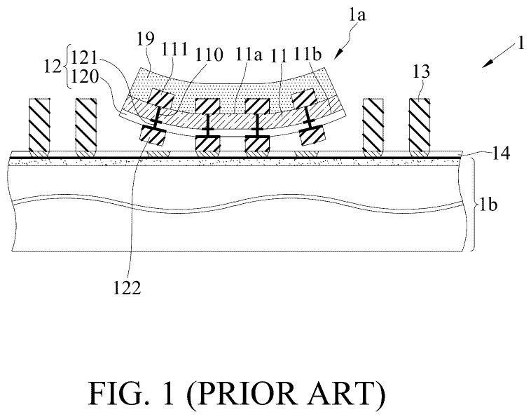

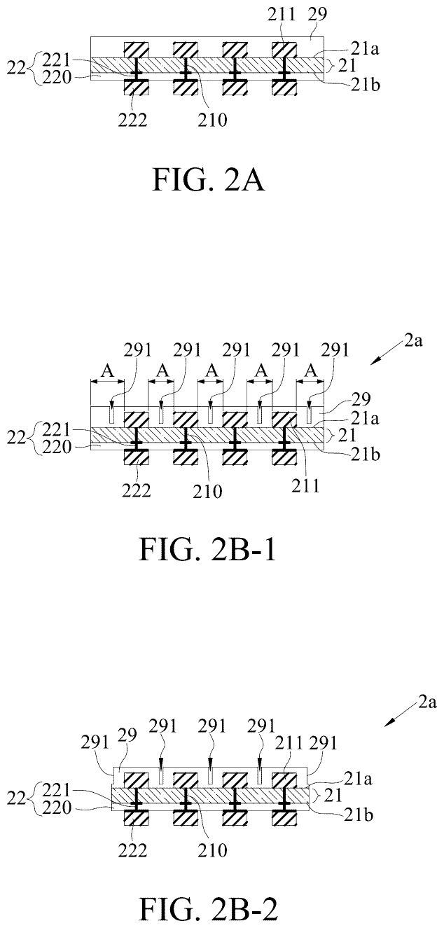

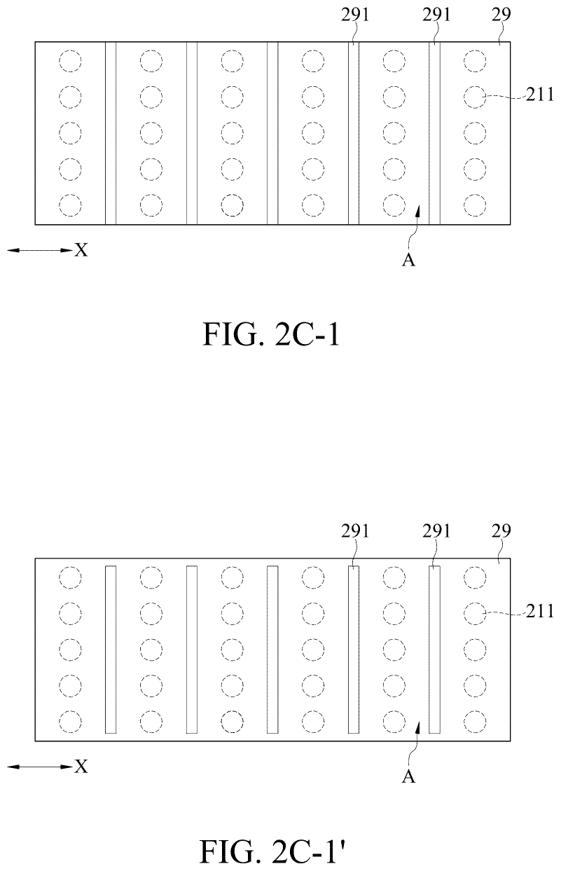

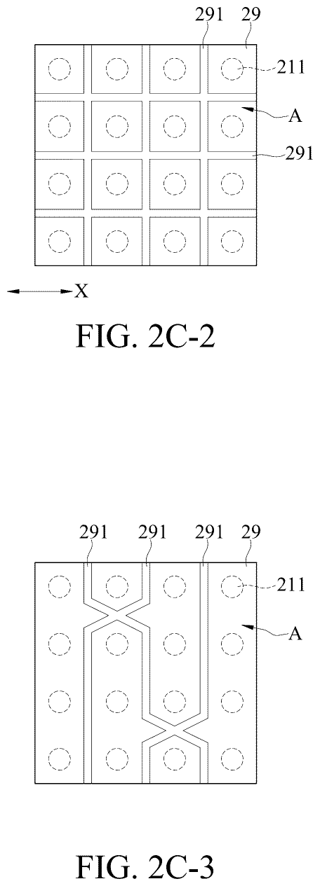

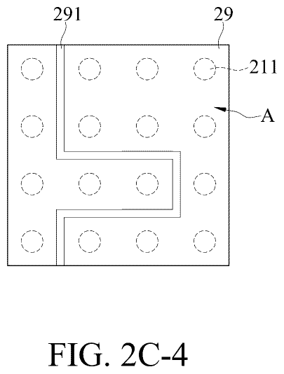

FIG. 2A and FIG. 2B-1 are schematic cross-sectional views illustrating a manufacturing method of an electronic structure 2a of the present disclosure.

As shown in FIG. 2A, a semiconductor substrate is provided as an electronic body 21. The electronic body 21 has a first surface 21a and a second surface 21b opposing the first surface 21a. A plurality of conductive bumps 211 are formed on the first surface 21a of the electronic body 21, and a plurality of external bumps 222 are formed on the second surface 21b of the electronic body 21. Then, a protective layer 29 is formed on the first surface 21a of the electronic body 21, such that the protective layer 29 covers the plurality of conductive bumps 211.

In an embodiment, the electronic body 21 is a semiconductor chip, and a plurality of conductive vias 210 are formed in the electronic body 21 and in communication with the first surface 21a and the second surface 21b, such that the conductive vias 210 are electrically connected to the plurality of conductive bumps 211. For example, the conductive vias 210 are through-silicon vias (TSVs), and a circuit portion 22 can be formed on the second surface 21b of the electronic body 21 according to requirements. The circuit portion 22 comprises at least one insulating layer 220 and conductive traces 221 bonded to the insulating layer 220, such that the conductive traces 221 are electrically connected to the conductive vias 210 and the external bumps 222. It should be understood that there are many aspects of the semiconductor components with the conductive vias 210, and the present disclosure is not limited to as such.

Moreover, the conductive bumps 211 are metal pillars such as copper pillars, such that the protective layer 29 covers the top surfaces and side surfaces of the conductive bumps 211. It should be understood that part of the protective layer 29 can be removed by a leveling process according to requirements, so that the top surfaces of the conductive bumps 211 are exposed from the protective layer 29, i.e., the top surfaces of the conductive bumps 211 are flush with the top surface of the protective layer 29.

Furthermore, the external bumps 222 are copper bumps or solder balls (made of solder material) for example, and can be encapsulated by a cladding layer in the subsequent processes. It should be understood that a non-conductive film (NCF) can be used as a bonding layer to encapsulate the external bumps 222 according to requirements, or an underfill may also be used to encapsulate the external bumps 222 for example. There are many aspects related to the external bumps 222, and the present disclosure is not limited to as such.

In addition, the protective layer 29 can be made of, for example, polybenzoxazole (PBO), polyimide (PI), prepreg (PP), epoxy resin, or other dielectric materials.

As shown in FIG. 2B-1, the area outside the plurality of conductive bumps 211 and in the protective layer 29 is defined as an open area A, and a plurality of grooves 291 are formed in the open area A of the protective layer 29 by laser processing so as to obtain the electronic structure 2a of the present disclosure.

In an embodiment, the plurality of grooves 291 do not penetrate through the protective layer 29, i.e., the plurality of grooves 291 are not exposed from the first surface 21a of the electronic body 21, the depth of each of the grooves 291 is less than the thickness of the protective layer 29, and the plurality of grooves 291 are not exposed from the side surfaces of the protective layer 29. In other words, the grooves 291 do not extend to the edges of the electronic body 21.

In an embodiment, as shown in FIG. 2B-2, some of the plurality of grooves 291 are exposed from the side surfaces of the protective layer 29, that is, the grooves 291 extend to the edges of the electronic body 21.

In an embodiment, as shown in FIG. 2C-1, as the electronic body 21 is in a rectangular shape, the direction that the warpage occurs is the long side direction X of the electronic body 21, in this case, the extending direction of the plurality of grooves 291 is a single direction and is perpendicular to the long side direction X of the electronic body 21, and each of the grooves 291 extends to the edge of the electronic body 21. It should be understood that each one of the grooves 291 may not extend to the edge of the electronic body 21, as shown in FIG. 2C-1′.

In an embodiment, as shown in FIG. 2C-2, as the electronic body 21 is in a square shape, the direction that the warpage occurs might be irregular, in this case, the extending directions of the plurality of grooves 291 are transverse and longitudinal and are mutually perpendicular, i.e., the plurality of grooves 291 are parallel and perpendicular to the long side direction X respectively, thereby the plurality of grooves 291 present a grid form.

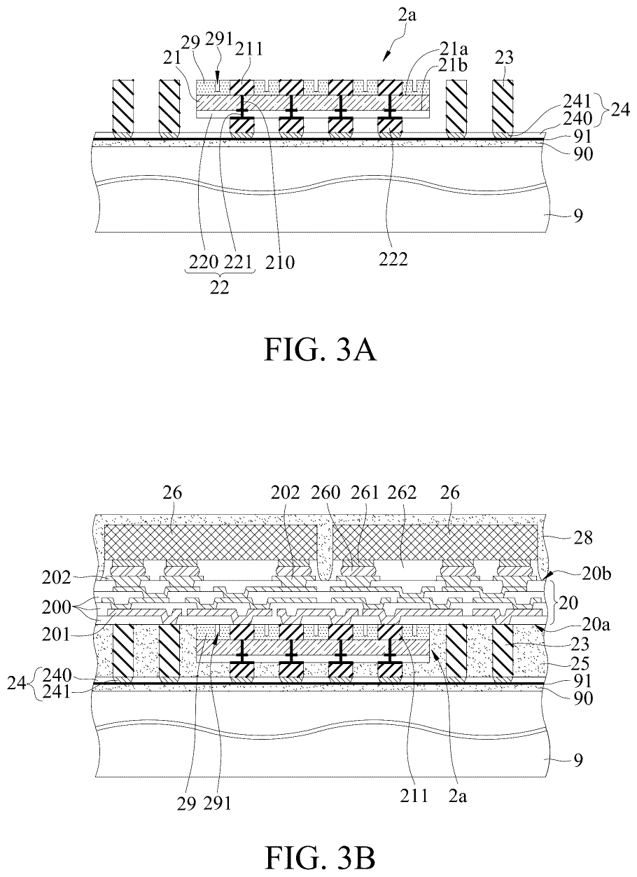

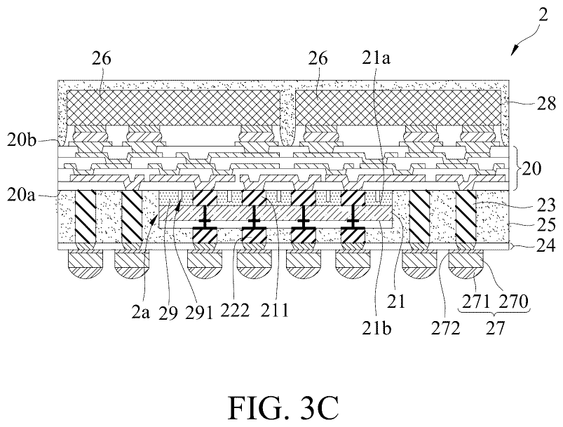

In an embodiment, the extending directions of the grooves 291 can be designed according to the conditions of different requirements for releasing the stresses caused by the shape of the electronic body 21, such that the extending direction of each of the grooves 291 is arranged irregularly (for instance, as shown in FIG. 2C-3, each of the grooves 291 is perpendicular to the long side direction X but the grooves 291 intersect with one another; or, as shown in FIG. 2C-4, the groove 291 has multiple bending points, etc.). It should be understood that the quantity, extending direction(s), arrangement of the grooves 291, or whether the grooves 291 are exposed from the side surfaces of the protective layer 29, are not limited in the present disclosure, as long as the grooves 291 are located in the open area A and can release the stress effectively.

FIG. 3A, FIG. 3B and FIG. 3C are schematic cross-sectional views illustrating a manufacturing method of an electronic package 2 of the present disclosure. In this embodiment, the electronic structure 2a shown in FIG. 2B-1 is adopted.

As shown in FIG. 3A, a carrier 9 is provided, and at least one electronic structure 2a and a plurality of conductive pillars 23 are disposed on the carrier 9.

The carrier 9 is, for example, a plate body made of semiconductor material (such as silicon or glass), and a release layer 90 and a metal layer 91 made of such as titanium/copper can be sequentially formed on the carrier 9 by such as coating, so that a carrier structure 24 can be formed on the metal layer 91, wherein the electronic structure 2a is disposed on the carrier structure 24 with the second surface 21b of the electronic body 21 thereof facing to the carrier 9.

In an embodiment, the carrier structure 24 comprises at least one dielectric layer 240 and a circuit layer 241 bonded to the dielectric layer 240. For example, the material used to form the dielectric layer 240 is polybenzoxazole (PBO), polyimide (PI), prepreg (PP), or other dielectric materials, and the circuit layer 241 and the dielectric layer 240 may be formed by the process of a redistribution layer (RDL).

The second surface 21b of the electronic body 21 of the electronic structure 2a is disposed on the circuit layer 241 of the carrier structure 24 via the plurality of external bumps 222.

In an embodiment, the occurrence of warpage of the electronic structure 2a can be avoided since the plurality of grooves 291 are formed in the protective layer 29, so that the plurality of external bumps 222 can be disposed on the circuit layer 241 effectively, and the electronic structure 2a can be firmly disposed on the carrier structure 24 by reflowing the external bumps 222 subsequently, thereby avoiding the problem of non-wetting solder.

The conductive pillars 23 are disposed on the carrier structure 24 and electrically connected to the circuit layer 241.

In an embodiment, the material used to form the conductive pillars 23 may be metal material such as copper or solder material. For example, by exposure and development, the conductive pillars 23 are formed by electroplating on the circuit layer 241.

As shown in FIG. 3B, a cladding layer 25 is formed on the carrier structure 24, such that the cladding layer 25 encapsulates the electronic structure 2a and the conductive pillars 23. It should be understood that the top surface of the protective layer 29, the end surfaces of the conductive bumps 211, the grooves 291 and the end surfaces of the conductive pillars 23 can be exposed from and flush with the surface of the cladding layer 25 by a leveling process. For example, the leveling process removes part of the material of the protective layer 29, part of the material of the conductive pillars 23, part of the material of the conductive bumps 211 and part of the material of the cladding layer 25 by grinding.

In an embodiment, the cladding layer 25 is made of insulating material, such as polyimide (PI), dry film, molding encapsulant such as epoxy (epoxy resin), or molding compound. For example, the cladding layer 25 can be formed on the carrier structure 24 by liquid compound, lamination, or compression molding, etc.

Next, a circuit structure 20 is formed on the cladding layer 25, such that the circuit structure 20 is electrically connected to the plurality of conductive pillars 23 and the plurality of conductive bumps 211, wherein the circuit structure 20 has a first side 20a and a second side 20b opposing the first side 20a, such that the first surface 21a of the electronic body 21 of the electronic structure 2a is bonded onto the first side 20a of the circuit structure 20.

In an embodiment, the circuit structure 20 comprises at least one insulating layer 200 and at least one redistribution layer (RDL) 201 formed on the insulating layer 200, such that the redistribution layer 201 is electrically connected to the plurality of conductive pillars 23 and the plurality of conductive bumps 211, wherein the outermost insulating layer 200 can be served as a solder-resist layer, and the outermost redistribution layer 201 is exposed from the solder-resist layer and served as electrical contact pads 202 such as micro pads (μ-pads).

Moreover, the material used to form the redistribution layer 201 is copper, and the material used to form the insulating layer 200 may be, for example, a dielectric material such as polybenzoxazole (PBO), polyimide (PI), prepreg (PP), or a solder-resist material such as solder mask (e.g., green solder mask), graphite (e.g., ink), etc.

Afterward, a plurality of electronic components 26 are disposed on the second side 20b of the circuit structure 20, then the electronic components 26 are encapsulated by an encapsulation layer 28.

In an embodiment, each of the electronic components 26 is an active component, a passive component, or a combination of the active component and the passive component, wherein the active component is, for example, a semiconductor chip, and the passive component is, for example, a resistor, a capacitor, or an inductor. In an embodiment, the electronic components 26 are, for example, semiconductor chips such as graphics processing units (GPUs), high bandwidth memories (HBMs), etc., and the electronic structure 2a is served as a bridge die and is electrically connected to the circuit structure 20 via the conductive bumps 211, thereby electrically bridging at least two electronic components 26.

Furthermore, each of the electronic components 26 has a plurality of conductive bumps 261 such as copper pillars and is electrically connected to the electrical contact pads 202 via a plurality of solder materials 260 such as solder bumps. In an embodiment, an under bump metallurgy (UBM) layer (not shown) may be formed on the electrical contact pads 202 or the electronic components 26 to facilitate bonding with the solder materials 260 or the conductive bumps 261.

In addition, the encapsulation layer 28 is made of insulating material, such as polyimide (PI), dry film, molding encapsulant such as epoxy (epoxy resin), or molding compound, and the encapsulation layer 28 can be formed on the circuit structure 20 by lamination or molding. It should be understood that the material used to form the encapsulation layer 28 may be the same as or differ from the material of the cladding layer 25.

Moreover, an underfill 262 can be formed between the electronic components 26 and the circuit structure 20 first to encapsulate the conductive bumps 261 and the solder materials 260, then the encapsulation layer 28 is formed to encapsulate the underfill 262 and the electronic components 26. Or, in other embodiments, the encapsulation layer 28 can encapsulate the electronic components 26 and the conductive bumps 261 at the same time without the need to form the underfill 262.

As shown in FIG. 3C, the carrier 9 and the release layer 90 thereon are removed, and then the metal layer 91 is removed, so that the carrier structure 24 is exposed.

In an embodiment, the metal layer 91 is served as a barrier (and can be used for electroplating the circuit layer 241 as well) as the release layer 90 is being removed so as to prevent the carrier structure 24 from being damaged, and then the metal layer 91 is removed by etching after the carrier 9 and the release layer 90 thereon are removed, such that the circuit layer 241 is exposed.

Then, a singulation process is performed, and a plurality of conductive components 27 are formed on the carrier structure 24, such that the conductive components 27 are electrically connected to the circuit layer 241, thereby obtaining the electronic package 2.

In an embodiment, each of the conductive components 27 comprises a metal bump 270 made of such as copper material and a solder material 271 formed on the metal bump 270. For example, an under bump metallization (UBM) layer 272 can be formed on the circuit layer 241 to facilitate bonding with the metal bumps 270. It should be understood that as the number of contacts (inputs/outputs or IOs) is insufficient, the RDL process can still be used to carry out the build-up operation (the layer-adding operation) to reconfigure the number and position of the IOs of the carrier structure 24.

In an embodiment, according to requirements, part of the material of the encapsulation layer 28 can be removed by a leveling process such as grinding, so that the upper surface of the encapsulation layer 28 is flush with the inactive surfaces of the electronic components 26, such that the electronic components 26 are exposed from the encapsulation layer 28 (not shown).

Furthermore, the electronic package 2 can be disposed on an electronic device (not shown) such as a packaging substrate or a circuit board via the conductive components 27.

Therefore, in the manufacturing method of the present disclosure, the plurality of grooves 291 are formed in the protective layer 29 of the electronic structure 2a to effectively release stress and prevent the electronic structure 2a from warping, so that the occurrence of the non-wetting problem of the solder for the external bumps 222 can be avoided in the subsequent processes.

The present disclosure provides an electronic structure 2a, which comprises an electronic body 21, a plurality of conductive bumps 211, a plurality of external bumps 222, a protective layer 29 and a plurality of grooves 291.

The electronic body 21 has a first surface 21a and a second surface 21b opposing the first surface 21a, and a plurality of conductive vias 210 connecting the first surface 21a and the second surface 21b are formed in the electronic body 21.

The conductive bumps 211 are formed on the first surface 21a of the electronic body 21 and electrically connected to the plurality of conductive vias 210.

The external bumps 222 are formed on the second surface 21b of the electronic body 21.

The protective layer 29 is formed on the first surface 21a of the electronic body 21 and covers the plurality of conductive bumps 211, and the area outside the plurality of conductive bumps 211 and in the protective layer 29 is defined as an open area A.

In an embodiment, a circuit portion 22 and the plurality of external bumps 222 can be formed on the second surface 21b of the electronic body 21 according to requirements, and the circuit portion 22 comprises at least one insulating layer 220 and conductive traces 221 bonded to the insulating layer 220, such that the conductive traces 221 are electrically connected to the conductive vias 210 and the external bumps 222.

The plurality of grooves 291 are formed in the open area A of the protective layer 29 by laser processing. In an embodiment, the plurality of grooves 291 do not penetrate through the protective layer 29, i.e., the plurality of grooves 291 are not exposed from the first surface 21a of the electronic body 21, and the depth of each of the grooves 291 is less than the thickness of the protective layer 29.

In an embodiment, the plurality of grooves 291 are not exposed from the side surfaces of the protective layer 29, i.e., the grooves 291 do not extend to the edges of the electronic body 21. In another embodiment, some of the plurality of grooves 291 are exposed from the side surfaces of the protective layer 29, i.e., the grooves 291 extend to the edges of the electronic body 21.

In an embodiment, as the electronic body 21 is in a rectangular shape, the direction in which the warpage occurs is the long side direction X of the electronic body 21, in this case, the extending direction of the plurality of grooves 291 is a single direction and is perpendicular to the long side direction X of the electronic body 21.

In an embodiment, as the electronic body 21 is in a square shape, the direction in which the warpage occurs may be irregular, in this case, the extending directions of the plurality of grooves 291 are transverse and longitudinal and are mutually perpendicular, i.e., the plurality of grooves 291 are parallel and perpendicular to the long side direction X respectively, thereby the plurality of grooves 291 present a grid form. In another embodiment, the extending directions of the grooves 291 can be designed according to the conditions of different requirements for releasing the stresses caused by the shape of the electronic body 21, such that the extending direction of each of the grooves 291 is arranged irregularly (for instance, each of the grooves 291 is perpendicular to the long side direction X but the grooves 291 intersect with one another; or, the groove 291 has multiple bending points, etc.).

The present disclosure further provides an electronic package 2, which comprises the electronic structure 2a, a carrier structure 24, a circuit structure 20, a plurality of conductive pillars 23, a cladding layer 25, a plurality of electronic components 26, a plurality of conductive components 27 and an encapsulation layer 28.

The carrier structure 24 comprises at least one dielectric layer 240 and a circuit layer 241 bonded to the dielectric layer 240. The second surface 21b of the electronic body 21 of the electronic structure 2a is disposed on the circuit layer 241 of the carrier structure 24 via the plurality of external bumps 222.

The conductive pillars 23 are disposed on the carrier structure 24 and electrically connected to the circuit layer 241.

The cladding layer 25 is formed on the carrier structure 24 and covers the electronic structure 2a and the conductive pillars 23, and the top surface of the protective layer 29, the end surfaces of the conductive bumps 211, the grooves 291 and the end surfaces of the conductive pillars 23 are exposed from and flush with the surface of the cladding layer 25.

The circuit structure 20 is formed on the cladding layer 25 and has a first side 20a and a second side 20b opposing the first side 20a, and the first surface 21a of the electronic body 21 of the electronic structure 2a is disposed on the first side 20a of the circuit structure 20.

In an embodiment, the circuit structure 20 comprises at least one insulating layer 200 and at least one redistribution layer 201 formed on the insulating layer 200, such that the redistribution layer 201 is electrically connected to the plurality of conductive pillars 23 and the plurality of conductive bumps 211, wherein the outermost insulating layer 200 can be served as a solder-resist layer, and the outermost redistribution layer 201 is exposed from the solder-resist layer and served as electrical contact pads 202 such as micro pads (μ-pads).

The electronic components 26 are disposed on the second side 20b of the circuit structure 20, and the encapsulation layer 28 is formed on the second side 20b of the circuit structure 20 and encapsulates the electronic components 26, wherein each of the electronic components 26 has a plurality of conductive bumps 261 such as copper pillars and is electrically connected to the electrical contact pads 202 via a plurality of solder materials 260 such as solder bumps. The electronic structure 2a is served as a bridge die and is electrically connected to the circuit structure 20 via the conductive bumps 211, thereby electrically connecting at least two electronic components 26.

In an embodiment, an underfill 262 can be formed between the electronic components 26 and the circuit structure 20 to encapsulate the conductive bumps 261 and the solder materials 260. Or, in other embodiments, the encapsulation layer 28 can encapsulate the electronic components 26 and the conductive bumps 261 at the same time without the need to form the underfill 262.

The conductive components 27 are formed on the carrier structure 24 and are electrically connected to the circuit layer 241, wherein each of the conductive components 27 comprises a metal bump 270 made of such as copper material and a solder material 271 formed on the metal bump 270, and an under bump metallization layer 272 can be formed on the circuit layer 241 to facilitate bonding with the metal bumps 270.

In summary, in the electronic structure and electronic package and the manufacturing method thereof of the present disclosure, the plurality of grooves are formed in the protective layer of the electronic structure to effectively release stress and prevent the electronic structure from warping, so that the occurrence of the non-wetting problem of the solder for the external bumps can be avoided in the subsequent processes. In addition, the electronic structure and electronic package and the manufacturing method thereof of the present disclosure can be accomplished by the existing processes and equipment, so there won't be a lot of extra costs.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic structure, comprising:
an electronic body having a first surface and a second surface opposing the first surface;
a plurality of conductive bumps disposed on the first surface of the electronic body;
a protective layer formed on the first surface of the electronic body and covering the plurality of conductive bumps, wherein an area outside the plurality of conductive bumps and in the protective layer is defined as an open area; and
a plurality of grooves formed in the protective layer and located in the open area.

2. The electronic structure of claim 1, wherein the plurality of grooves do not penetrate through the protective layer.

3. The electronic structure of claim 1, wherein some of the plurality of grooves are exposed from side surfaces of the protective layer.

4. The electronic structure of claim 1, wherein an extending direction of the plurality of grooves is a single direction.

5. The electronic structure of claim 1, wherein extending directions of the plurality of grooves are transverse and longitudinal and are mutually perpendicular, whereby the plurality of grooves present a grid form.

6. The electronic structure of claim 1, wherein an extending direction of each of the plurality of grooves is arranged irregularly.

7. An electronic package, comprising:
a circuit structure having a first side and a second side opposing the first side;
the electronic structure of claim 1 disposed on the first side of the circuit structure via the first surface of the electronic body; and
a plurality of electronic components disposed on the second side of the circuit structure and electrically connected to the circuit structure, wherein the electronic structure is electrically connected to the circuit structure via the plurality of conductive bumps to electrically connect at least two of the plurality of electronic components.

8. The electronic package of claim 7, further comprising a cladding layer encapsulating the electronic structure.

9. The electronic package of claim 7, further comprising an encapsulation layer encapsulating the plurality of electronic components.

10. The electronic package of claim 7, further comprising a carrier structure carrying the electronic structure, wherein the second surface of the electronic body of the electronic structure is disposed on the carrier structure via a plurality of external bumps, and the electronic structure is electrically connected to the carrier structure.

11. The electronic package of claim 10, further comprising a plurality of conductive pillars disposed on and electrically connected to the carrier structure and surrounding the electronic structure.

12. A method of manufacturing an electronic structure, comprising:
providing an electronic body having a first surface and a second surface opposing the first surface;
forming a plurality of conductive bumps on the first surface of the electronic body;
forming a protective layer on the first surface of the electronic body to cover the plurality of conductive bumps, wherein an area outside the plurality of conductive bumps and in the protective layer is defined as an open area; and
forming a plurality of grooves in the protective layer, wherein the plurality of grooves are located in the open area.

13. The method of claim 12, wherein the plurality of grooves do not penetrate through the protective layer.

14. The method of claim 12, wherein some of the plurality of grooves are exposed from side surfaces of the protective layer.

15. The method of claim 12, wherein an extending direction of the plurality of grooves is a single direction.

16. The method of claim 12, wherein extending directions of the plurality of grooves are transverse and longitudinal and are mutually perpendicular, whereby the plurality of grooves present a grid form.

17. The method of claim 12, wherein an extending direction of each of the plurality of grooves is arranged irregularly.

18. A method of manufacturing an electronic package, comprising:
providing a circuit structure and the electronic structure of claim 1, wherein the circuit structure has a first side and a second side opposing the first side;
disposing the first surface of the electronic body of the electronic structure on the first side of the circuit structure; and
disposing a plurality of electronic components on the second side of the circuit structure, wherein the plurality of electronic components are electrically connected to the circuit structure, wherein the electronic structure is electrically connected to the circuit structure via the plurality of conductive bumps to electrically connect at least two of the plurality of electronic components.

19. The method of claim 18, further comprising forming a cladding layer to encapsulate the electronic structure.

20. The method of claim 18, further comprising forming an encapsulation layer to encapsulate the plurality of electronic components.

21. The method of claim 18, further comprising disposing the second surface of the electronic body of the electronic structure on a carrier structure via a plurality of external bumps, wherein the electronic structure is electrically connected to the carrier structure.

22. The method of claim 21, further comprising forming a plurality of conductive pillars on the carrier structure, wherein the plurality of conductive pillars surround the electronic structure and are electrically connected to the carrier structure.
